(19) United States
(12) Patent Application Publication
(10) Pub. No.: US 2017/0148528 A1
(43) Pub. Date: May 25, 2017

(54) SEMICONDUCTOR DEVICE AND SEMICONDUCTOR SYSTEM INCLUDING THE SAME

(71) Applicant: SK hynix Inc., Gyeonggi-do (KR)

(72) Inventor: Ho-Sung CHO, Gyeonggi-do (KR)

(21) Appl. No.: 15/150,284

(22) Filed: May 9, 2016

(30) Foreign Application Priority Data
Nov. 24, 2015 (KR) 10-2015-0164531

(51) Int. Cl. G11C 29/12; G11C 11/4096

(52) U.S. Cl. CPC G11C 29/12; G11C 11/4096

(57) ABSTRACT

A semiconductor device includes: a target block to be tested; a test control block suitable for testing the target block according to a predetermined test process that is based on a test program data; and a test result processing block suitable for generating a processing order data corresponding to a processing order of the test process where failure occurs, based on a test result of the test control block.

### CROSS-REFERENCE TO RELATED APPLICATIONS

The present application claims priority of Korean Patent Application No. 10-2015-0164531, filed on Nov. 24, 2015, which is incorporated herein by reference in its entirety.

### BACKGROUND

1. Field

Exemplary embodiments of the present invention relate generally to a semiconductor design technology and, more particularly, to a semiconductor device and a semiconductor system including the same.

2. Description of the Related Art

As technologies for semiconductor fabricating processes are advanced, a greater number of elements and internal circuits for performing various functions are integrated into a single semiconductor device. As complexity of a semiconductor device increases, various methods for testing the semiconductor device have been suggested.

For example, a test apparatus having a stand-alone machine structure may be used. However, if there are not enough pads or similar means which enable direct access to a semiconductor device, the test apparatus having the stand-alone machine structure cannot be used for testing the semiconductor device.

As an alternative, a method of integrating a built-in self-test (BIST) circuit into a semiconductor device is suggested. The semiconductor device including the BIST circuit does not need to connect to a test apparatus through numerous pads or similar means, and may be tested at high speed.

FIG. 1 is a block diagram illustrating a conventional semiconductor system 100.

Referring to FIG. 1, the conventional semiconductor system 100 includes a control device 110 and a semiconductor device 120.

The control device 110 generates a test program data PDATA and transfers the test program data PDATA to the semiconductor device 120. In addition, the control device 110 receives a failure address data ADATA from the semiconductor device 120. For example, the control device 110 may include a central processing unit (CPU).

The semiconductor device 120 performs a self-test on a test target block included therein according to a predetermined test process that is based on the test program data PDATA, and generates the failure address data ADATA corresponding to a result of the self-test. For example, the semiconductor device 120 may include a memory device, such as a dynamic random access memory (DRAM).

FIG. 2 is a detailed diagram of the semiconductor device 120 of FIG. 1.

Referring to FIG. 2, the semiconductor device 120 includes a memory block 121, a test program storing block 123, a test control block 125, and a failure address generation block 127.

The memory block 121 corresponds to the test target block and includes a plurality of memory cells. The memory block 121 performs sequentially a test operation corresponding to the test process and outputs a result data MDATA obtained through the test operation to the test control block 125 based on test control information (i.e., a command signal and an address signal CMD/ADD). For example, the memory block 121 sequentially performs a write operation and/or a read operation according to the test process and generates a read data obtained through the read operation as the result data MDATA.

The test program storing block 123 stores the test program data PDATA received from the control device 110.

The test control block 125 performs a test on the memory cells according to the test process that is based on the test program data PDATA′ stored in the test program storing block 123 for determining whether there exists a failure memory cell. For example, the test control block 125 outputs the test control information CMD/ADD corresponding to the test process to the memory block 121 and determines whether a failure memory cell exists or not based on the result data MDATA. For example, the test control block 125 includes a BIST circuit.

The failure address generation block 127 generates the failure address data ADATA corresponding to an address of the failure memory cell based on the determination result information RES00 outputted from the test control block 125. For example, the failure address generation block 127 generates an address when a failure occurs as the failure address data ADATA.

FIG. 3 is a detailed diagram of the control device 110 of FIG. 1.

Referring to FIG. 3, the control device 110 includes a test pattern generation block 111 and a failure address storing block 113.

The test pattern generation block 111 generates the test program data PDATA. The failure address storing block 113 stores the failure address data ADATA.

The control device 110 outputs the test program data PDATA to the semiconductor device 120, and then the semiconductor device 120 performs the self-test based on the test program data PDATA.

The test control block 125 controls write data to be written in the memory cells and read data to be read from the memory cells according to the test process. The test control block 125 determines whether a failure memory cell occurs among the memory cells based on the write data and the read data. The failure address generation block 127 generates and stores the failure address data ADATA corresponding to an address of the failure memory cell determined by the test control block 125. When the self-test terminates, the failure address generation block 127 transfers the failure address data ADATA to the control device 110.

However, the conventional semiconductor system 100 has the following concern.

The semiconductor device 120 transfers only the failure address data ADATA generated through the self-test to the control device 110. For this reason, the control device 110 recognizes only a location of the failure memory cell. Thus, other information on failure cannot be recognized by the control device 110.

It is desired that the semiconductor device 120 generates more information on failure (hereinafter, referred to as “failure log information”), such as, for example, a cause of the failure, and the address of the failure memory cell as the test result. However, although the semiconductor device 120 generates the failure log information, the semiconductor device 120 requires the failure address generation block 127 to have an enormous capacity for storing the failure log information. In addition, the cost associated with testing the semiconductor system 100 increases when the required time for transmitting the failure log information is included in the overall test time.

### SUMMARY

Various embodiments of the present invention are directed to a semiconductor device that may generate failure log information including a cause of failure and an address of a failure memory cell.

Furthermore, various embodiments of the present invention are directed to a semiconductor system that may easily generate the failure log information.

Furthermore, various embodiments of the present invention are directed to a semiconductor device that may generate the failure log information with a minimum bit number, and a semiconductor system including the semiconductor device.

In accordance with an embodiment of the present invention, a semiconductor device includes: a target block to be tested; a test control block suitable for testing the target block according to a predetermined test process that is based on a test program data; and a test result processing block suitable for generating a processing order data corresponding to a processing order of the test process where failure occurs, based on a test result of the test control block.

The test result may include a command signal corresponding to the test process and a failure guide signal corresponding to a moment when the failure occurs.

The test result processing block may count the processing order of the test process, and generate a counting value of the processing order, which corresponds to the moment when the failure occurs, as the processing order data.

The test control block may include a built-in, self-test (BIST) circuit.

The semiconductor device may further include: a storing block suitable for storing the test program data.

In accordance with another embodiment of the present invention, a semiconductor device includes: a memory block including a plurality of memory cells; a test control block suitable for testing the memory cells in order according a predetermined test process that is based on a test program data; and a test result processing block suitable for generating a processing order data corresponding to a processing order of the test process where failure occurs, based on a test result of the test control block.

The test result may include a read command signal corresponding to the test process and a failure guide signal corresponding to a moment when the failure occurs.

The test result processing block may count the processing order of the test process, and generate a counting value of the processing order, which corresponds to the moment when the failure occurs, as the processing order data.

The test control block may include a BIST circuit.

The semiconductor device of claim may further include: a storing block suitable for storing the test program data.

In accordance with another embodiment of the present invention, a semiconductor system includes: a semiconductor device suitable for internally testing a target block according to a predetermined test process that is based on a test program data, and generating a processing order data corresponding to a processing order of the test process where failure occurs during the test; and a control device suitable for generating the test program data, and generating failure log information of the test target block based on the test program data and the processing order data.

The control device may track the test process based on the test program data and the processing order data to generate the failure log information.

The control device may include: a test pattern generation block suitable for generating the test program data; a failure analysis block suitable for generating the failure log information based on the test program data and the processing order data; and a storing block suitable for storing the test program data, the processing order data and the failure log information.

The target block may include a memory block having a plurality of memory cells.

The failure log information may include address information of a memory cell where failure occurs among the memory cells and failure type information of the memory cell where the failure occurs.

The semiconductor device may include: the memory block; a test control block suitable for testing the memory cells in order according to the test process that is based on the test program data; and a test result processing block suitable for generating the processing order data based on a test result of the test control block.

The test result may include a read command signal corresponding to the test process and a failure guide signal corresponding to a moment when the failure occurs.

The test result processing block may count the processing order of the test process and generate a counting value of the processing order, which corresponds to the moment when the failure occurs, as the processing order data.

The test control block may include a BIST circuit.

The semiconductor device may further include a storing block suitable for storing the test program data.

### BRIEF DESCRIPTION OF THE DRAWINGS

FIG. 1 is a block diagram illustrating a conventional semiconductor system.

FIG. 2 is a detailed diagram of a semiconductor device of FIG. 1.

FIG. 3 is a detailed diagram of a control device of FIG. 1.

FIG. 4 is a block diagram illustrating a semiconductor system, according to an embodiment of the present invention.

FIG. 5 is a detailed diagram of a semiconductor device of FIG. 4, according to an embodiment of the invention.

FIG. 6 is a detailed diagram of a control device of FIG. 4, according to an embodiment of the invention.

### DETAILED DESCRIPTION

Various embodiments of the present invention are described below in more detail with reference to the accompanying drawings. The present invention may, however, be embodied in different forms and should not be construed as being limited to the embodiments set forth herein. Rather, these embodiments are provided so that this disclosure is thorough and complete, and fully convey the present invention to those skilled in the art. Throughout the disclosure, like reference numerals refer to like parts throughout the various figures and embodiments of the present invention.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, indicate the presence of stated features, but do not preclude the presence or addition of one or more other features. As used herein, the term “and/or” indicates any and all combinations of one or more of the associated listed items. It is also noted that in this specification, “connected/coupled” refers to one component not only directly coupling another component but also indirectly coupling another component through an intermediate component.

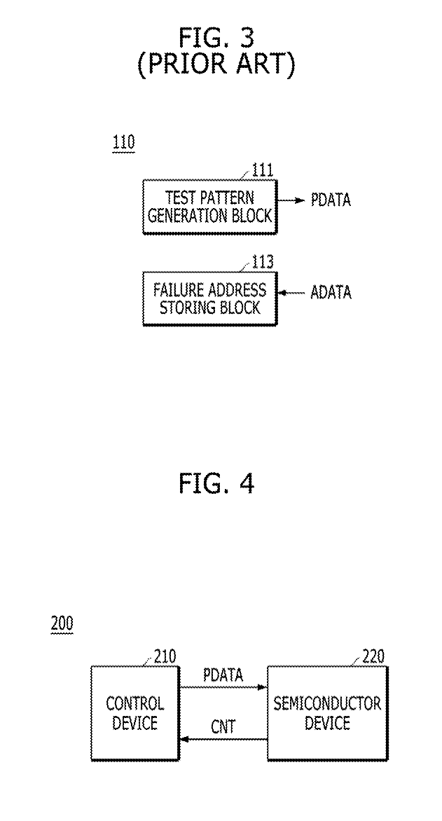

FIG. 4 is a block diagram illustrating a semiconductor system 200, according to an embodiment of the present invention.

Referring to FIG. 4, the semiconductor system 200 may include a control device 210 and a semiconductor device 220.

The control device 210 may generate a test program data PDATA and transfer the test program data PDATA to the semiconductor device 220. The control device 210 may analyze the test program data PDATA and a processing order data CNT received from the semiconductor device 200 to generate failure log information FLOG (see FIG. 6) of a test target block included in the semiconductor device 220. For example, the control device 210 may include a central processing unit (CPU).

The semiconductor device 220 may perform a self-test on the test target block included therein according to a predetermined test process that is based on the test program data PDATA, and generate the processing order data CNT, which corresponds to a processing order of the test process where failure occurs during the self-test, to transfer to the control device 210. For example, the semiconductor device 220 may include a memory device such as a dynamic random access memory (DRAM).

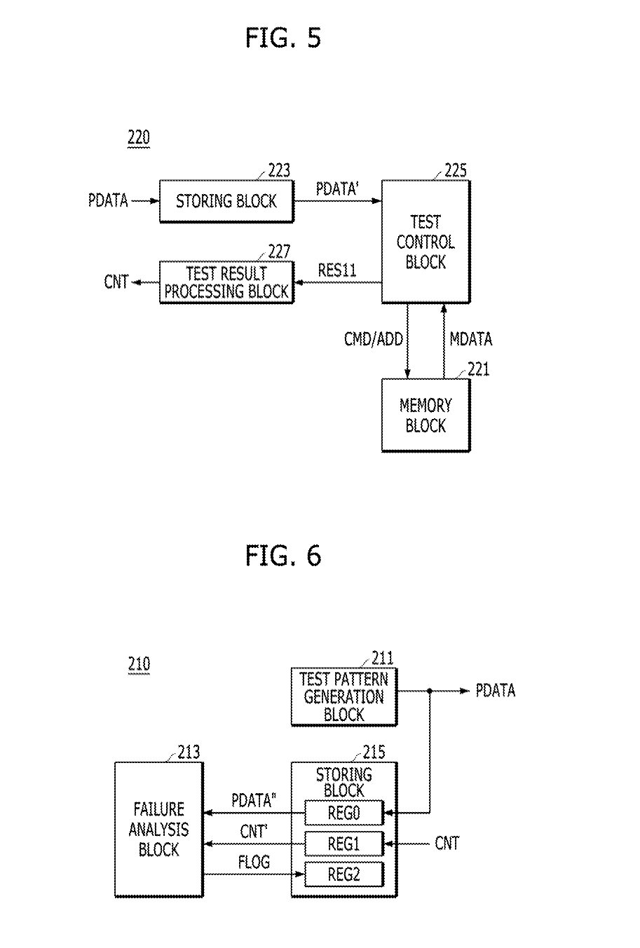

FIG. 5 is a detailed diagram of the semiconductor device 220 of FIG. 4.

Referring to FIG. 5, the semiconductor device 220 may include a memory block 221, a storing block 223, a test control block 225, and a test result processing block 227.

The memory block 221, i.e., a target block to be tested, may include a plurality of memory cells. The memory block 221 may perform sequentially a test operation corresponding to the test process that is based on test control information (i.e., a command signal and an address signal CMD/ADD) generated from the test control block 225 and output a result data MDATA obtained through the test operation to the test control block 225. For example, the memory block 221 may sequentially perform a write operation and/or a read operation according to the test process and generate a read data obtained through the read operation as the result data MDATA.

The storing block 223 may store the test program data PDATA. When the test program data PDATA includes selection information, the storing block 223 may have a storage capacity corresponding to the selection information. The selection information may be single information for selecting one kind of test process among several kinds of test processes. When the test program data PDATA includes test pattern information, the storing block 223 may have a storage capacity corresponding to the test pattern information. The test pattern information may be complex information for generally controlling the test process.

The test control block 225 may perform a self-test on the memory cells according to the test process that is based on the test program data PDATA′ stored in the storing block 223 to determine whether a failure memory cell exists or not. For example, the test control block 225 may output the test control information CMD/ADD corresponding to the test process to the memory block 221 and determine whether the failure memory cell exists or not based on the test control information CMD/ADD and the corresponding result data MDATA. The test control information CMD/ADD may include command signals (e.g., a write command signal and a read command signal), a write data signal required for a write operation, an address signal corresponding to the memory cells, a clock signal and so on.

When the test program data PDATA′ includes the selection information, the test control block 225 may perform the self-test based on one kind of a test process corresponding to the test program data PDATA′ among the several kinds of test processes that are stored. In this case, the test pattern information corresponding to the several kinds of test processes may have to be stored in the test control block 225, in advance. On the other hand, when the test program data PDATA′ includes the test pattern information, the test control block 225 may perform the test based on the test process corresponding to the test program data PDATA′. In this case, the test pattern information does not need to be stored in the test control block 225 in advance.

The test control block 225 may supply test result information RES11 corresponding to a result of the self-test to the test result processing block 227. For example, the test control block 225 may include a BIST circuit. The test result information RES11 may include the read command signal, and a failure guide signal corresponding to a moment when failure occurs. Or, the test result information RES11 may include the clock signal and the failure guide signal.

The test result processing block 227 may generate the processing order data CNT based on the test result information RES11. For example, the test result processing block 227 may count the processing order of the test process based on the read command signal or the clock signal, and generate a counting value for the processing order, which corresponds to the moment when the failure occurs, as the processing order data CNT based on the failure guide signal.

FIG. 6 is a detailed diagram of the control device 210 of FIG. 4, according to an embodiment of the invention.

Referring to FIG. 6, the control device 210 may include a test pattern generation block 211, a failure analysis block 213, and a storing block 215.

The test pattern generation block 211 may generate the test program data PDATA. As described above, the test program data PDATA may include the selection information or the test pattern information.

The failure analysis block 213 may analyze the test program data PDATA′ stored in the storing block 215 and the processing order data CNT′ to generate failure log information FLOG. For example, the failure analysis block 213 may track the test process based on the test program data PDATA′ and the processing order data CNT′. The failure log information FLOG may include address information of a memory cell where failure occurs, and failure type information of the memory cell where the failure occurs. The failure type information may correspond to a cause of failure, such as, for example, failure relating to a margin, or failure due to a row hammering phenomenon.

The storing block 215 may store the test program data PDATA, the processing order data CNT, and the failure log information FLOG. For example, the storing block 215 may include a first register REG0 for storing the test program data PDATA, a second register REG1 for storing the processing order data CNT, and a third register REG2 for storing the failure log information FLOG.

The control device 210 outputs the test program data PDATA to the semiconductor device 220, and then the semiconductor device 220 may perform the self-test based on the test program data PDATA.

The test control block 225 may control the write operation so that the write data may be written in the memory cells. The test control block 225 may control the read operation to read the read data from the memory cells. The test control block 225 may determine the failure memory cell among the memory cells based on the write data and the read data and generate the failure guide signal at the moment when the failure occurs based on the determination result. The test control block 225 may supply the read command signal corresponding to the read operation and the failure guide signal to the test result processing block 227 as the test result information RES11. The test control block 225 may supply the clock signal that toggles from a moment when the self-test starts to be performed and the failure guide signal to the test result processing block 227 as the test result information RES11.

The test result processing block 227 may generate the processing order data CNT based on the test result information RES11. For example, the test result processing block 227 may count the number of times that the read command signal is inputted, corresponding to the processing order of the test process, and may generate a counting value of the number of times corresponding to the moment when the failure occurs as the processing order data CNT based on the failure guide signal. The test result processing block 227 may count the number of times that the clock signal toggles, which correspond to the processing order of the test process, and may generate a counting value of the number of times corresponding to the moment when the failure occurs as the processing order data CNT based on the failure guide signal.

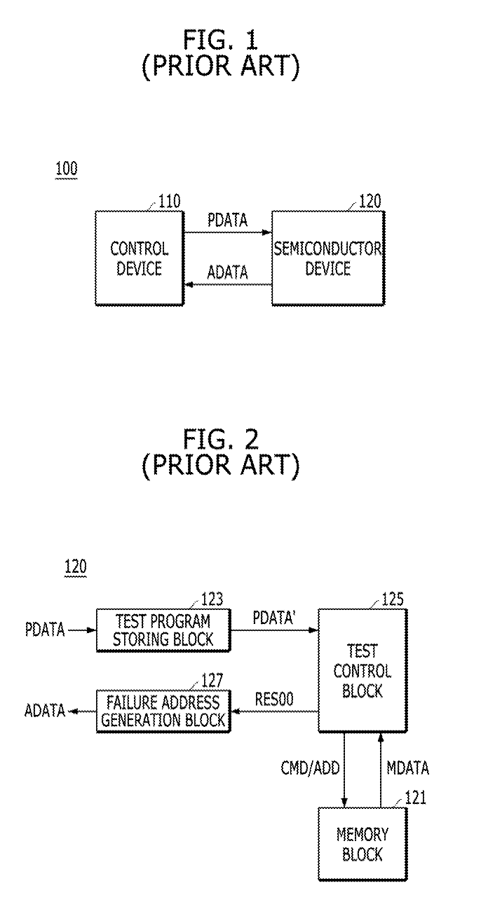

Since the processing order data CNT includes just the counting value, the processing order data CNT may have a similar bit number to the failure address information (see ADATA of FIG. 1) described above or may have a smaller bit number than the failure address information ADATA.

When the semiconductor device 220 outputs the processing order data CNT to the control device 210 as a result of the self-test, the control device 210 may analyze the test program data PDATA and the processing order data CNT to generate the failure log information FLOG of the semiconductor device 220.

When the test program data PDATA and the processing order data CNT are stored in the storing block 215, the failure analysis block 213 may analyze the test program data PDATA′ stored in the storing block 215 and the processing order data CNT′ to generate the failure log information FLOG. For example, the failure analysis block 213 may track the test process based on the test program data PDATA′ and the processing order data CNT′. The failure log information FLOG may include the address information of the memory cell where failure occurs among the memory cells, and the failure type information of the memory cell where the failure occurs. The failure type information may correspond to a cause of failure (e.g., failure relating to a margin, or failure due to a row hammering phenomenon). In other words, the failure analysis block 213 may generate the address information by analyzing how many times the read command signal is inputted when the failure occurs, based on the processing order data CNT′. The failure analysis block 213 may generate the address information by analyzing how many times the clock signal toggles when the failure occurs, based on the processing order data CNT′. In addition, the failure analysis block 213 may generate the failure type information by analyzing a test pattern before the failure occurs, based on the test program data PDATA′.

According to the embodiments of the present invention, failure log information having a minimum bit number may be generated, and failure type information, such as, for example, a type and a cause of failure as well as address information of a memory cell where the failure occurs may be analyzed based on the failure log information.

According to embodiments of the present invention, the failure log information is stored and transmitted with a similar bit number or a smaller bit number to or than an address of the failure memory cell, hence, the cost associated with a test may be reduced.

While the present invention has been described with respect to specific embodiments, the embodiments are not intended to be restrictive, but rather descriptive. Further, it is noted that the present invention may be achieved in various ways through substitution, change, and modification, by those skilled in the art without departing from the spirit and or scope of the present invention as defined by the following claims.

What is claimed is:

1. A semiconductor device, comprising:
a target block to be tested;
a test control block suitable for testing the target block according to a predetermined test process that is based on a test program data; and
a test result processing block suitable for generating a processing order data corresponding to a processing order of the test process where failure occurs, based on a test result of the test control block.

2. The semiconductor device of claim 1, wherein the test result includes a command signal corresponding to the test process and a failure guide signal corresponding to a moment when the failure occurs.

3. The semiconductor device of claim 2, wherein the test result processing block counts the processing order of the test process, and generates a counting value of the processing order, which corresponds to the moment when the failure occurs, as the processing order data.

4. The semiconductor device of claim 1, wherein the test control block includes a built-in, self-test (BIST) circuit.

5. The semiconductor device of claim 1, further comprising:
a storing block suitable for storing the test program data.

6. A semiconductor device, comprising:
a memory block including a plurality of memory cells;
a test control block suitable for testing the memory cells in order according a predetermined test process that is based on a test program data; and
a test result processing block suitable for generating a processing order data corresponding to a processing order of the test process where failure occurs, based on a test result of the test control block.

7. The semiconductor device of claim 6, wherein the test result includes a read command signal corresponding to the test process and a failure guide signal corresponding to a moment when the failure occurs.

8. The semiconductor device of claim 6, wherein the test result processing block counts the processing order of the test process, and generates a counting value of the processing order, which corresponds to the moment when the failure occurs, as the processing order data.

9. The semiconductor device of claim 6, wherein the test control block includes a BIST circuit.

10. The semiconductor device of claim 6, further comprising:
a storing block suitable for storing the test program data.

11. A semiconductor system, comprising:
a semiconductor device suitable for internally testing a target block according to a predetermined test process that is based on a test program data, and generating a processing order data corresponding to a processing order of the test process where failure occurs during the test; and
a control device suitable for generating the test program data, and generating failure log information of the test target block based on the test program data and the processing order data.

12. The semiconductor system of claim 11, wherein the control device tracks the test process based on the test program data and the processing order data to generate the failure log information.

13. The semiconductor system of claim 11, wherein the control device includes:
a test pattern generation block suitable for generating the test program data;
a failure analysis block suitable for generating the failure log information based on the test program data and the processing order data; and
a storing block suitable for storing the test program data, the processing order data and the failure log information.

14. The semiconductor system of claim 11, wherein the target block includes a memory block having a plurality of memory cells.

15. The semiconductor system of claim 14, wherein the failure log information includes address information of a memory cell where failure occurs among the memory cells and failure type information of the memory cell where the failure occurs.

16. The semiconductor system of claim 14, wherein the semiconductor device includes:
the memory block;
a test control block suitable for testing the memory cells in order according to the test process that is based on the test program data; and
a test result processing block suitable for generating the processing order data based on a test result of the test control block.

17. The semiconductor system of claim 16, wherein the test result includes a read command signal corresponding to the test process and a failure guide signal corresponding to a moment when the failure occurs.

18. The semiconductor system of claim 16, wherein the test result processing block counts the processing order of the test process and generates a counting value of the processing order, which corresponds to the moment when the failure occurs, as the processing order data.

19. The semiconductor system of claim 16, wherein the test control block includes a BIST circuit.

20. The semiconductor system of claim 16, wherein the semiconductor device further includes a storing block suitable for storing the test program data.
